(19) United States
(12) Patent Application Publication
(10) Pub. No.: US 2023/0394187 A1
(43) Pub. Date: Dec. 7, 2023

(54) ANALYSIS OF BRIDGE-PILE FOUNDATION SYSTEM IN MULTI-LAYERED NON-LINEAR SOIL STRATA USING ENERGY-BASED METHOD

(71) Applicant: FLORIDA ATLANTIC UNIVERSITY BOARD OF TRUSTEES, Boca Raton, FL (US)

(72) Inventors: Arvan Prakash ANKITHA, Deerfield Beach, FL (US); Madasamy AROCKIASAMY, Boca Raton, FL (US); Marco AMATO, Trento (IT)

(21) Appl. No.: 18/204,677

(22) Filed: Jun. 1, 2023

Related U.S. Application Data
(60) Provisional application No. 63/347,890, filed on Jun. 1, 2022.

(51) Int. Cl. G06F 30/13; G01V 99/00

(52) U.S. Cl. CPC G06F 30/13; G01V 99/005

(57) ABSTRACT

Disclosed is a method for analyzing displacement responses of piles subjected to at least one loading condition selected from an axial load, a lateral load, and a bending moment. Also disclosed is a non-transitory machine-readable storage medium including instructions executable by a processing resource of a computing device to cause the processing resource to perform the inventive method.

### CROSS REFERENCE TO RELATED APPLICATION

This application claims priority to and benefit of U.S. provisional patent application Ser. No. 63/347,890 filed Jun. 1, 2022, which is fully incorporated by reference and made a part hereof.

### BACKGROUND

### 1. Field of the Invention

This invention relates to structural/geotechnical engineering.

### 2. Description of Related Art

Structures such as high-rise buildings, bridges, offshore platforms, etc., which rest on piles embedded in multi-soil strata (see, e.g., FIG. 1), are acted upon by various horizonal forces (e.g., waves, currents and seismic events), vertical forces and moments. Although extensive research has been carried out in the area of soil pile interaction, analysis and design of a pile embedded in multi-soil strata still poses a challenge.

Numerous studies have been reported in published literature on analytical solutions for a pile foundation system installed in a homogeneous single soil layer. However, piles are rarely installed in an ideal homogeneous single soil layer.

Studies of pile foundation systems installed in multilayered soil have also been reported. See, e.g., Basu et al. “Analysis of laterally loaded piles in multilayered soil deposits.” Joint Transportation Research Program (2008): 330, and Hashem-Ali. “Analytical methods for predicting load-displacement behaviour of piles.” PhD diss., Durham University, 2014.

Despite the foregoing developments, it is desired to provide a method and a device for further advancing the existing analytical techniques and contribute to better understanding of the behavior of deep foundation systems in non-linear soil strata.

All references cited herein are incorporated herein by reference in their entireties.

### SUMMARY

A first aspect comprises a method for analyzing displacement responses of piles subjected to at least one loading condition selected from an axial load, a lateral load, and a bending moment, includes the following steps: (a) inputting values r₀, L, λ, G₀, Eₚ, Pₜ, and ν; (b) calculating γ1, old and γ2, old; (c) determining integrations of soil parameters C, k and m; (d) calculating soil dimensionless function ϕ; (e) calculating pile displacement ν; (f) calculating γ1, new and γ2, new; (g) determining whether a condition (γ_{old}−γ_{new})/γ_{old}<0.001 is true; and (h) repeating steps (a)-(g) until the condition is true.

A second aspect comprises a non-transitory machine-readable storage medium including instructions executable by a processing resource of a computing device to cause the processing resource to perform the above inventive method.

Another aspect comprises a method for analyzing displacement responses of a pile subjected to a lateral loading condition. One embodiment of the method comprises inputting values r₀, L, λ, G₀, Eₚ, and Iₚ, and applying force and moments, Q₀ and M₀; choosing initial values of y₁, y₂, y₃, y₄, y₅, y₆, y₇ and y₈, and calculating ϕᵣ and ϕ_{θ}; calculating deviatoric strain ε_{q}, and using the deviatoric strain to calculate soil stiffness, G, where

$$G = {{G}_{0} ( \frac{{ε}_{q}}{{ε}_{qo}} )}^{n} ;$$

calculating nₛ₁, nₛ₂, mₛ₁, mₛ₂ and mₛ₃; calculating pile displacement u; calculating calculate y₁^{new} y₂^{new} y₃^{new} y₄^{new} y₅^{new} y₆^{new} y₇^{new} and y₈^{new}; determining whether a condition y_{old}−y_{new})/y_{old}<0.001 is true; and repeating the above steps until the condition is true.

And yet another aspect comprises a non-transitory machine-readable storage medium including instructions executable by a processing resource of a computing device to cause the processing resource to perform the above method for analyzing displacement responses of a pile subjected to a lateral loading condition.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF SEVERAL VIEWS OF THE DRAWINGS

The invention will be described in conjunction with the following drawings in which like reference numerals designate like elements and wherein:

FIG. 1 is a schematic view of a high-rise building and its foundation resting on multilayered soil strata.

FIG. 2 is a screenshot of an exemplary graphical user interface of an embodiment of software according to the invention.

FIG. 3 is a graph of depth against pile deflection calculated by the method of the invention and by several comparative methods.

FIG. 4 illustrates an axially loaded pile in an isotropic non-linear elastic medium.

FIGS. 5A and 5B illustrate stresses and displacements within a soil continuum where FIG. 5A illustrates stresses within a soil continuum and FIG. 5B illustrates displacements within a soil continuum.

FIGS. 6A and 6B illustrate discretization of the soil where FIG. 6A illustrates a top view and FIG. 6B illustrates a front view.

FIG. 7 illustrates the variation of normalizing shear secant with logarithmic strain ε_{q} or normalized displacement.

FIG. 8 illustrates degradation of tangent with deviatoric strain.

FIG. 9 illustrates logarithmic scale of degradation of tangent stiffness with strain level.

FIG. 10 is an exemplary flowchart depicting the iterative solution procedure for calculating pile head displacements when axially (vertically) loaded.

FIG. 11 illustrates a laterally loaded pile in layered non-linear elastic medium.

FIG. 12 is an exemplary flowchart depicting the iterative solution procedure for calculating pile displacements when laterally loaded.

FIGS. 13, 14 and 15 are exemplary annotated screenshots of graphical user interfaces of embodiments of software according to the invention.

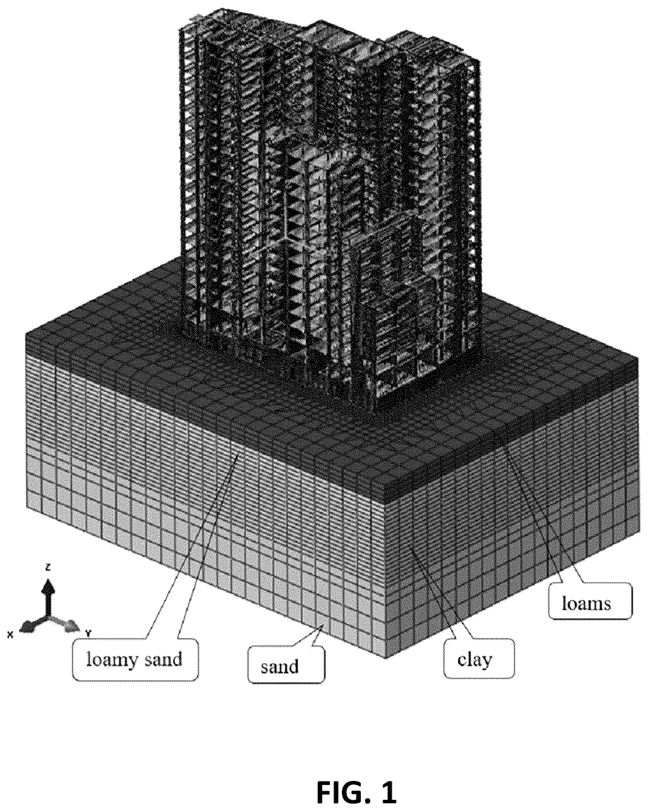

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes—from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of embodiments and to the Figures and their previous and following description.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions may be loaded onto a general-purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems, including for example cloud-based systems, that perform the specified functions or steps, or combinations of special purpose hardware and computer instructions.

The increasing demand for adopting pile foundations in bridges has pointed towards the need to constantly improve the existing analytical techniques for better understanding of the behavior of such foundation systems. Disclosed and described herein are embodiments of an energy-based approach (simplified continuum model) to assess the displacement responses to general loading conditions (e.g., axial (e.g., vertical) load, lateral load and bending moment) of piles embedded in multilayered soil strata considering the soil non-linear behavior. The governing differential equations and the boundary conditions for a bridge pile embedded in multi-layered soil strata subjected to the general loading conditions are obtained using the Hamilton's principle employing variational principles and minimization of energies.

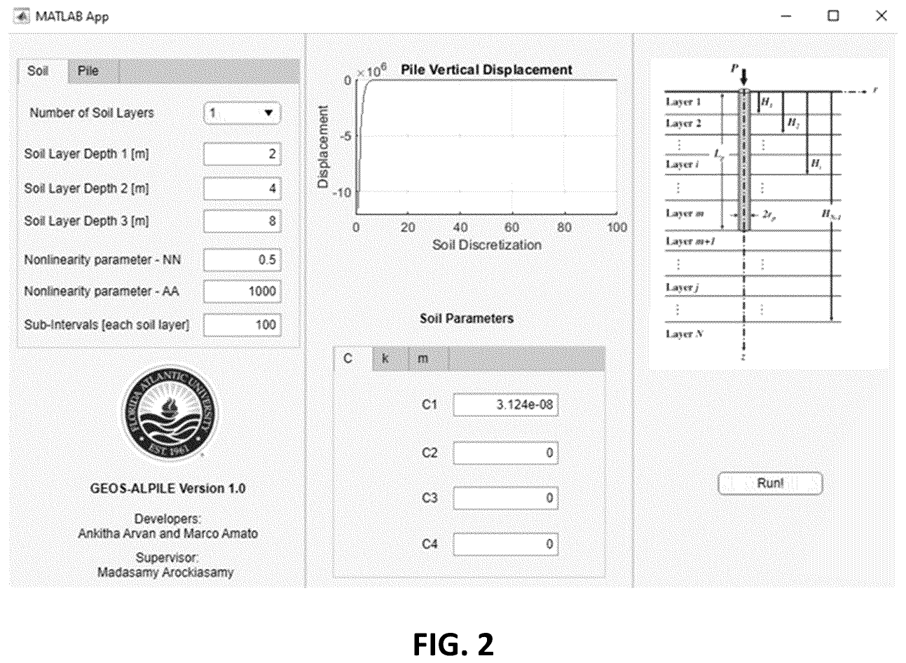

Soil discretization (non-linearity) has been incorporated through simple constitutive relationships that account for degradation of soil moduli with increasing strain values. The soil moduli (λ, and G) are assumed to vary in radial, circumference and depth directions according to the strain and stress levels. A simple power law, which was developed where the soil is assumed to be nonlinear elastic and perfectly plastic, is used. A Tresca yield surface is assumed to develop the soil stiffness variation with different strain levels that defines the non-linearity of the soil strata. This numerical technique can be applied to a pile foundation in multi-layered soil strata for a pier supporting the bridge and solved by customizing the software using, for example, MATLAB™ (The MathWorks, Inc., Natick, MA) R2019a (see FIG. 2). The inventive method is preferably based on the Finite Difference Method since it yields results faster when compared to the Finite Element Method.

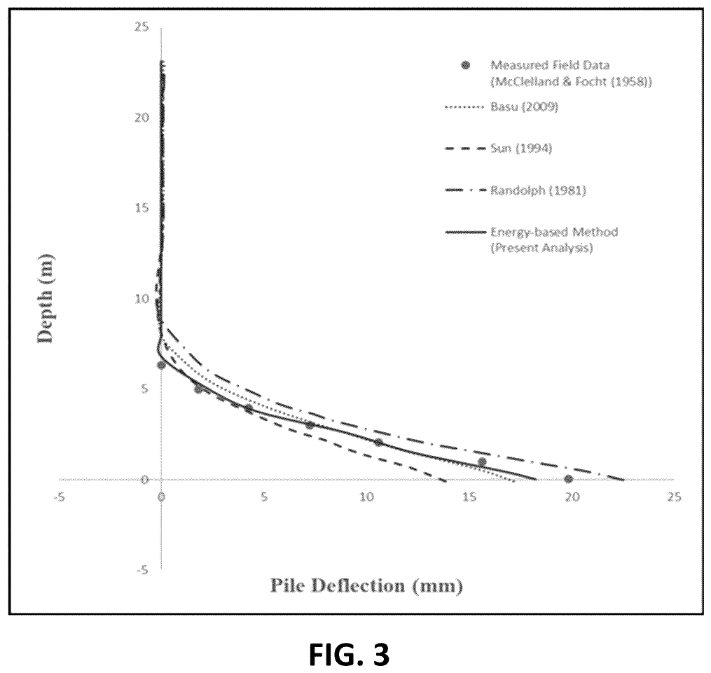

The analysis yields the bridge pile displacements at any depth along the length of the pile. The results from the energy-based method are compared with those from the field test data as well as the Finite Element Analysis based on, for example, the software ANSYS Workbench 2021 R1 (ANSYS, Inc., Canonsburg, PA). As shown in FIG. 3, the results of the analysis of embodiments described herein are in good agreement with the published field data of McClelland and Focht (McClelland et al. “Soil modulus for laterally loaded piles.” Transactions of the American Society of Civil Engineers 123, no. 1 (1958): 1049-1063) and the three-dimensional finite element analysis results performed using the software ANSYS 2019R3. The results obtained are in good agreement with the field data when compared to the linear elastic solution that does not consider the soil non-linearity.

The methodology can be extended to study the response of the multi-strata soil supporting group piles underneath bridge piers.

The inventive method includes obtaining load-displacement responses on a single pile embedded in multi-layered non-linear soil strata subjected to the general loading conditions (axial load, lateral load and a moment). The method has been developed in the following three steps: (i) a single pile embedded in multi-layered non-linear soil strata is assessed for displacements when subjected to axial loads; (ii) a single pile embedded in multi-layered non-linear soil strata is assessed for displacements when subjected to lateral loads and moments; and (iii) a single pile embedded in multi-layered non-linear soil strata is assessed for displacements when subjected to axial loads, lateral loads and moments (generally loaded pile). This is an analytical solution to assess the load-displacement responses given any field data and is effective in capturing the responses quite well when compared to the existing field test data and the finite element analyses. By further validation, it was proven to be sufficient in analyzing the responses without undue experimentation. Software programs have been developed which embody certain aspects of the invention. GEOS-ALPILE has been developed for axial loads, GEOS-LLPILE has been developed for lateral loads and moments and GEOS-GLPILE has been developed for general loads. The developed software works on an iterative procedure and are very user-friendly as inputs of basic pile and soil properties provide outputs within seconds. It can be used by practitioners, researchers and for academia purposes (e.g., by students to understand the responses in an easy way).

### I. Energy-Based Approach: Analysis of a Vertically Loaded Pile in Multi-Layered Non-Linear Soil Strata

Referring to Aryan, Prakash & Arockiasamy, Madasamy. (March, 2021). Energy-Based Approach for the Analysis of a Vertically Loaded Pile in Multi-layered Non-linear Soil Strata. 10.21203/rs.3.rs-337774/v1, which is fully incorporated by reference and made a part hereof, an analytical model has been developed based on the energy-based approach to predict the load-displacement responses of the piles embedded in multi-layered soil strata subjected to static axial loads.

Disclosed is an energy-based approach (simplified continuum model) to provide a displacement profile of an axially loaded pile in multi-layered soil strata considering the soil's non-linear elastic behavior. A mathematical framework is disclosed that considers the soil as a 3D elastic continuum and the pile is modeled following the elastic Euler-Bernoulli beam theory. The differential equations governing the soil and pile displacements have been obtained utilizing the principle of minimum potential energy assuming rational soil displacement functions. An iterative algorithm is adopted that solves the differential equations analytically and numerically. The study investigates the effect of explicit incorporation of soil properties and layering in order to understand the importance of predicting appropriate pile displacement responses in linear elastic soil system. The responses indicated that the effect of soil layers and their thicknesses, pile properties and the variation in soil moduli have a direct impact on the displacements of piles subjected to axial loading. Hence, proper emphasis has to be given to account for the soil non-linearity.

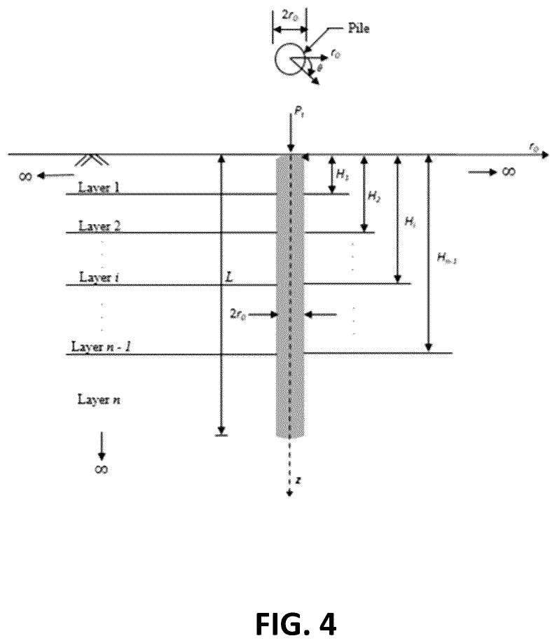

An axially loaded pile in an isotropic non-linear elastic multi-layered soil medium is shown in FIG. 4. This disclosure considers a pile of length L with circular cross section of radius r₀. The pile is embedded in n horizontal soil layers and is subjected to an axial (vertical) load Pₜ. The horizontal soil layers extend to infinity in the radial direction and the bottom n^{th} layer extends to infinity in the vertical direction.

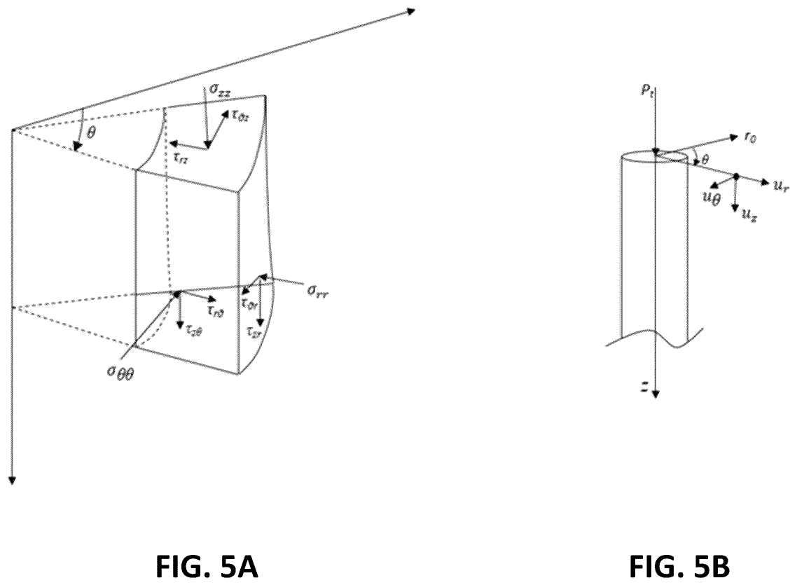

In FIG. 4, the terms H₁, H₂, H₃ . . . Hₙ₋₁ denote the vertical height from the ground surface to the bottom of any layer i. Therefore, the thickness of any layer i is Hᵢ−Hᵢ₋₁ with H₀=0. Due to the axisymmetric problem behavior, a system of cylindrical coordinates (r-θ-z) is chosen with the origin coinciding with the center of the pile cross section at the pile head and the z axis coinciding with the pile axis. The pile head is considered to be free, and the tip of the pile is clamped. Another important assumption to be noted is that there is no slippage or separation between the pile and the surrounding soil and between soil layers. The stresses and the displacement within a soil continuum are shown below in FIGS. 5A and 5B.

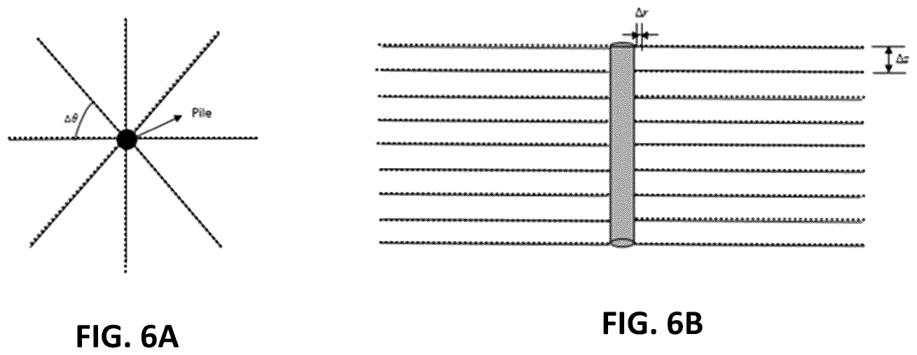

At each point in the soil domain, soil elastic parameters G and λ have been calculated (see FIGS. 6A and 6B). The disclosed methods obtain pile head deflection caused by the action of the vertical load at the pile head.

For an axially loaded pile, the horizontal and tangential displacements can be neglected as they are accompanied by very small strains. For the case of a pile with circular cross-section, there are two functions to be considered: ν(z), which will represent the vertical displacement at depth z and the dimensionless functions ϕ(r), describing the variation of soil displacements in the radial direction.

The vertical displacement at any point of the soil is represented as a function in (r, z):

νᵣ=0

ν_{θ}=0

ν_{z}(r, z)=ϕ(r)ν(z)

For a given uniform cross-sectional area of the pile along the length, ϕ(r)=1 when r=0 to r₀, whereas ϕ(r)=0 when r→∞. This explains the decay of the function ϕ(r) with an increase in the radial direction.

The pile and its surrounding elastic medium are subjected to a vertical displacement of the pile soil system when it is acted upon by a vertical load. The total potential energy of the pile and the soil is a summation of internal potential energy and external potential energy, which is given as:

$$Π = \frac{1}{2} {E}_{p} {A}_{p} {\int }_{0}^{L} {( ϕ \frac{d v}{d z} )}^{2} + \frac{1}{2} {\int }_{0}^{L} {\int }_{0}^{2 π} {\int }_{{r}_{0}}^{∞} {σ}_{i j} {ε}_{i j} r d r d θ + \frac{1}{2} {\int }_{L}^{∞} {\int }_{0}^{2 π} {\int }_{0}^{∞} {σ}_{i j} {ε}_{i j} rdr - {vP}_{t at z = 0} \qquad ( 1 )$$

where Eₚ denotes the elastic Young modulus of the pile, Aₚ denotes the cross-section of the pile, ν represents the vertical displacement, Pₜ is the vertical load and σᵢⱼ, εᵢⱼ are stress and strain components, respectively. The first term of the equation represents potential pile energy, the second and third terms are potential energy from the surrounding soil and the soil below the pile, respectively.

The soil non-linearity is considered by varying the soil elastic parameters (G and λ) at each discretized nodal point in the soil domain. The stress-strain and strain-displacement relationships at any given nodal point in the soil medium are idealized by the following relationships. The stress-strain relationship is expressed as:

$$[ \begin{matrix}{σ}_{r} \\ {σ}_{θ} \\ {σ}_{z} \\ {τ}_{r θ} \\ {τ}_{rz} \\ {τ}_{θ z}\end{matrix} ] = [ \begin{matrix}λ + 2 G & λ & λ & 0 & 0 & 0 \\ λ & λ + 2 G & λ & 0 & 0 & 0 \\ λ & λ & λ + 2 G & 0 & 0 & 0 \\ 0 & 0 & 0 & G & 0 & 0 \\ 0 & 0 & 0 & 0 & G & 0 \\ 0 & 0 & 0 & 0 & 0 & G\end{matrix} ] [ \begin{matrix}{ε}_{r} \\ {ε}_{θ} \\ {ε}_{z} \\ {γ}_{r θ} \\ {γ}_{rz} \\ {γ}_{θ z}\end{matrix} ] \qquad ( 2 )$$

where G and λ are the elastic constants of the soil. The strain-displacement relationship is given by:

$$[ \begin{matrix}{ε}_{r} \\ {ε}_{θ} \\ {ε}_{z} \\ {γ}_{r θ} \\ {γ}_{rz} \\ {γ}_{θ z}\end{matrix} ] = [ \begin{matrix}- \frac{\partial {u}_{r}}{\partial r} \\ - \frac{{u}_{r}}{r} - \frac{1}{r} \frac{\partial {u}_{θ}}{\partial θ} \\ - \frac{\partial {u}_{z}}{\partial z} \\ - \frac{1}{r} \frac{\partial {u}_{r}}{\partial θ} - \frac{\partial {u}_{θ}}{\partial r} + \frac{{u}_{θ}}{r} \\ - \frac{\partial {u}_{z}}{\partial r} - \frac{\partial {u}_{r}}{\partial z} \\ - \frac{1}{r} \frac{\partial {u}_{z}}{\partial θ} - \frac{\partial {u}_{θ}}{\partial z}\end{matrix} ] = [ \begin{matrix}0 \\ 0 \\ - ϕ ( r ) \frac{dv ( z )}{dz} \\ 0 \\ - v ( z ) \frac{d ϕ ( r )}{dr} \\ 0\end{matrix} ] \qquad ( 3 )$$

By substituting Equation (3) into Equation (2), the strain energy density function,

$$W = \frac{{σ}_{ij} {ε}_{ij}}{2}$$

is obtained, where the summation implies the repetition of the indices i and j as required in indicial notation:

$$\frac{1}{2} {σ}_{i j} {ε}_{i j} = \frac{1}{2} [ ( λ + 2 G ) {( ϕ \frac{d v}{d z} )}^{2} + {G ( v \frac{d ϕ}{dr} )}^{2} ] \qquad ( 4 )$$

Substituting Equation (4) into Equation (1) and integrating with respect to θ the potential energy equation becomes:

$$Π = \frac{1}{2} {E}_{p} {A}_{p} {\int }_{0}^{L} {( ϕ \frac{d v}{d z} )}^{2} + dz + π {\int }_{0}^{L} {\int }_{{r}_{0}}^{∞} ( ( λ + 2 G ) {( ϕ \frac{d v}{d z} )}^{2} + {G ( v \frac{d ϕ}{dr} )}^{2} ) rdrdz + π {\int }_{L}^{∞} {\int }_{0}^{∞} ( ( λ + 2 G ) {( ϕ \frac{d v}{d z} )}^{2} + {G ( v \frac{d ϕ}{dr} )}^{2} ) rdrdz - {vP}_{t at z = 0} \qquad ( 5 )$$

The variational principle has been used to calculate the potential energy δU and the external energy δW. As a result, the governing equations of the pile-soil system are obtained by minimizing the potential energy of soil and pile. The expression of potential energy contains different functions, such as ν(z), ϕ(r), dν(z)/dz and dϕ(r)/dr, and so minimizing the potential energy gives:

$$δΠ = [ A ( v ) δ v + B ( v ) δ ( \frac{d v}{d z} ) ] + [ C ( ϕ ) δϕ ] \qquad ( v )$$

where A, B and C are the terms associated with variations δν, δ(dν/dz) and δϕ.

The variation of Equation (5) becomes

$$δ \prod = \frac{1}{2} {E}_{p} {A}_{p} {\int }_{0}^{L} ϕ \frac{d v}{d z} δ ϕ \frac{d v}{d z} d z + π {\int }_{0}^{L} {\int }_{{r}_{0}}^{∞} ( ( λ + 2 G ) ( ϕ \frac{d v}{d z} δ ϕ \frac{d v}{d z} ) + G ( v \frac{d ϕ}{dr} δ v \frac{d ϕ}{dr} ) ) rdrdz + π {\int }_{L}^{∞} {\int }_{0}^{∞} ( ( λ + 2 G ) ( ϕ \frac{d v}{d z} δ ϕ \frac{d v}{d z} ) + G ( v \frac{d ϕ}{dr} δ v \frac{d ϕ}{dr} ) ) rdrdz - {vP}_{t at z = 0} \qquad ( 6 )$$

The governing equation of the pile is obtained for 0<z<L by collecting terms associated with δνdz, δ(dν/dz)dz and its derivative, δν and δ(dν/dz)dz≠0. The governing equation is obtained as follows:

$$k \frac{{d}^{2} v}{d {z}^{2}} + C \frac{d v}{d z} + m v = 0 \qquad ( 7 )$$

$$where$$

$$C = 2 π {\int }_{{r}_{0}}^{∞} r [ ( λ + 2 G ) {ϕ}^{2} ] dr \qquad ( 8 )$$

$$k = {E}_{p} {I}_{p} + 2 π {\int }_{{r}_{0}}^{∞} r [ ( λ + 2 G ) {ϕ}^{2} ] dr \qquad ( 9 )$$

$$m = - 2 π {\int }_{{r}_{0}}^{∞} r {G ( \frac{d ϕ}{dr} )}^{2} dr \qquad ( 10 )$$

The tip of a pile is assumed to be clamped, which means that the displacement and the curvature are equal to zero at the base of the pile. The boundary conditions are obtained by collecting δν and δ(dν/dz). At the head of the pile (z=0):

$$- {E}_{p} {A}_{p} - 2 π {\int }_{{r}_{0}}^{∞} [ λ + G ( 2 + {ϕ}^{2} ) ] d r \frac{d v}{d z} + {P}_{t} = 0 \qquad ( 11 )$$

The displacement at the tip of the pile (z=L):

ν=0 (12)

The second order differential Equation (7) can be solved using a central finite difference scheme. Equation (7) becomes

$$k ( \frac{{v}_{i - 1} - 2 {v}_{i} + {v}_{i + 1}}{Δ {z}^{2}} ) + C ( \frac{{v}_{i - 1} + {v}_{i + 1}}{Δ z} ) + m {v}_{i} = 0 \qquad ( 13 )$$

where i denotes the i^{th} node in z direction, and Δz is the distance between two nodes. This discretized analysis is then solved using software such as MATLAB R2019a or specifically-programmed software.

The governing equation of the soil is obtained for r₀≤r≤∞ by collecting terms associated with δϕdr:

$$r \frac{{d}^{2} ϕ}{{dr}^{2}} + {γ}_{1} \frac{d ϕ}{dr} + {γ}_{2} ϕ = 0 \qquad ( 14 )$$

$$where$$

$${γ}_{1} = \frac{{\int }_{0}^{L} G + rG}{{\int }_{0}^{L} G} \qquad ( 15 )$$

$${γ}_{2} = \frac{- {\int }_{0}^{L} ( λ + rG ) {( \frac{dv}{d z} )}^{2}}{{\int }_{0}^{L} G {v}^{2}} \qquad ( 16 )$$

Note that the dimensionless parameter γ, defined in the above equation, describes the function ϕ. Similar to the solution of Equation (7) by the central finite difference scheme, the governing differential Equation (14) is also solved using the FDM (using, for example, MATLAB R2019a software).

The variation of the shear stress with strain can be described using two parameters A and n that have been obtained experimentally using a pressuremeter test as shown in the equation below:

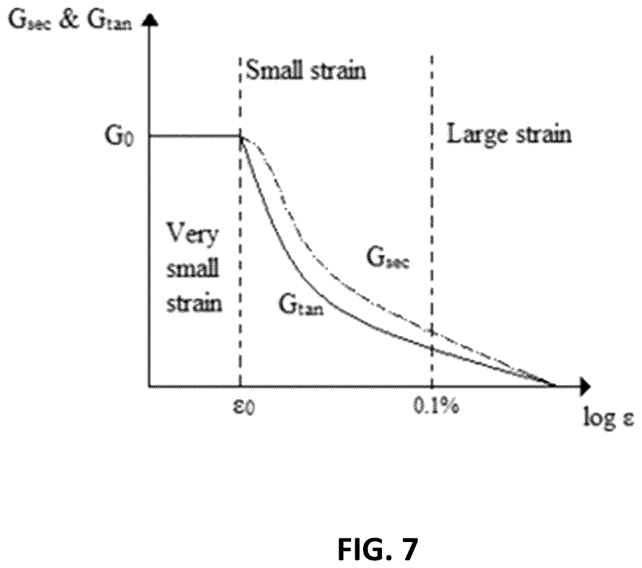

q=A(ε_{q})ⁿ (17)

where q represents the equivalent shear stress and ε_{q} is the deviator shear strain. It has been shown that the decay curves of the soil stiffness with strain can be divided into three regions as shown in FIG. 7. The first region in FIG. 7 represents the very small strain where the stiffness, G₀ is constant, the second region comprising small strains starts from ε₀ until ε=0.1% and the third region exceeds ε=0.1%, which is indicative of large strains.

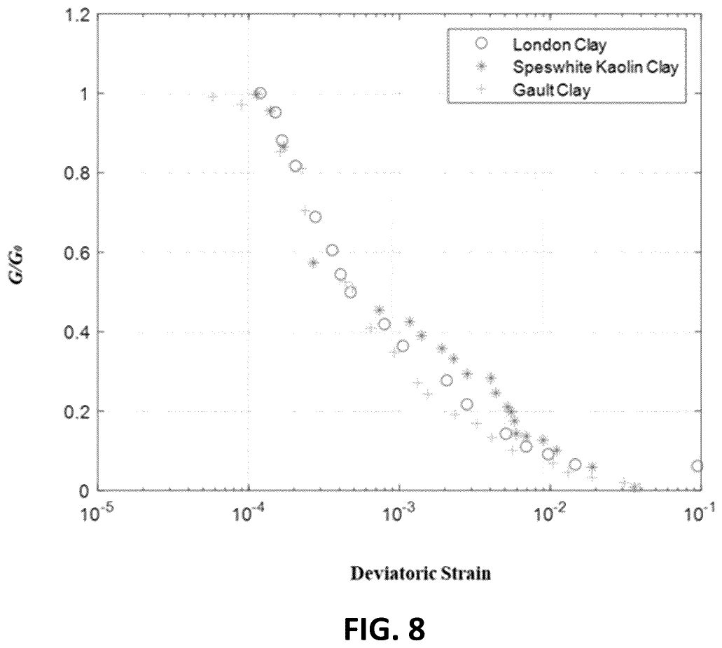

In the second region, the stiffness decays rapidly and in the third region with large strain levels, the stiffness is the smallest, which concludes that the soil stiffness is high at the small strain and decreases with the large strain. FIG. 8 shows the degradation of soil stiffness with increasing strains for different clay types.

This disclosure assumes decay of soil stiffness with strain using a power law to describe the stress-strain behavior of soil:

$$G = {{G}_{0} ( \frac{{ε}_{q}}{{ε}_{q 0}} )}^{n} \qquad ( 18 )$$

$$G = a {ε}_{q}^{n} \qquad ( 19 )$$

where

$$a = \frac{{G}_{0}}{{ε}_{q 0}^{n}}$$

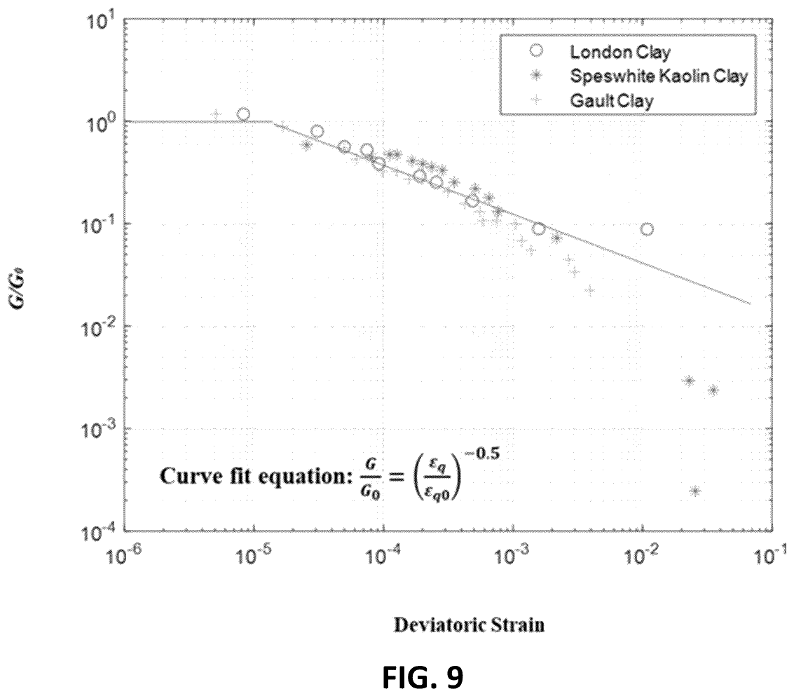

is a constant determined empirically; n describes soil nonlinearity which is equal to (−0.5) according to the experimental data analyzed by Osman et al. [Osman, A. S.; White, D. J.; Britto, A. M.; Bolton, M. D. Simple prediction of the undrained displacement of a circular surface foundation on non-linear soil. Géotechnique 2007, 57, 729-737, which is fully incorporated by reference], see FIG. 9.

$${ε}_{q} = \sqrt{\frac{2}{9} [ {( {ε}_{rr} - {ε}_{θ θ} )}^{2} + {( {ε}_{θ θ} - {ε}_{z z} )}^{2} + {( {ε}_{z z} - {ε}_{rr} )}^{2} ] + \frac{4}{3} ( {ε}_{r θ}^{2} + {ε}_{θ z}^{2} + {ε}_{zr}^{2} )}$$

represents the deviatoric strain; and ε_{q0} is the maximum deviatoric strain with linear elastic behavior which is equal to 10⁻⁵. The soil stiffness G is estimated by calculating the strain at each location followed by the power law.

The pile deflection equation can be solved when the soil and geometry related parameters k, C and m are known; however, these parameters depend on the unknown dimensionless soil function ϕ, which can be estimated by calculating γ₁ and γ₂. Soil displacement is obtained when the initial numbers of these values γ₁ and γ₂, are inserted into Equation (14), from which the parameters k, C and m are obtained as a result of the pile displacement. New values of γ₁ and γ₂ (Equations (15) and (16)) are determined and then inserted into Equation (19) to evaluate ϕ then ν, therefore, an iteration technique is needed to obtain the condition

$$\frac{{γ}_{o l d} - {γ}_{n e w}}{{γ}_{o l d}} < 0.001 .$$

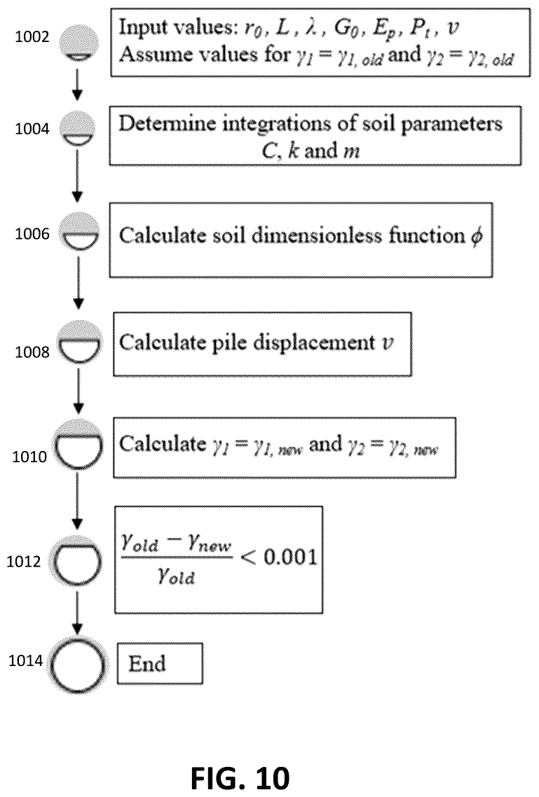

This iterative solution methodology (FIG. 10) is programmed in software (e.g., MATLAB R2019a) to obtain the pile head displacements.

FIG. 10 is an exemplary flowchart depicting the iterative solution procedure for calculating pile head displacements. FIG. 10 illustrates a method for analyzing displacement responses of piles subjected to at least one loading condition selected from the group consisting of an axial load, a lateral load, and a bending moment. The disclosed method comprises 1002, inputting values r₀, L, λ, G₀, Eₚ, Pₜ, and ν, and either assuming values for or calculating γ_{1, old} and γ_{2,old}. At 1004, integrations of soil parameters C, k and m are determined. At 1006, the soil dimensionless function ϕ is calculated. At 1008, the pile displacement ν is calculated. At 1010, γ_{1,new} and γ_{2,new} are calculated. At 1012, it is determined whether a condition (γ_{old}−γ_{new})/γ_{old}<0.001 is true. At 1014, steps 1002-1012 are repeated until the condition ((γ_{old}−γ_{new})/γ_{old}<0.001) is true.

### II. Energy-Based Approach: Analysis of a Laterally Loaded Pile in Multi-Layered Non-Linear Elastic Soil Strata

Referring to Prakash, Aryan Ankitha & Arockiasamy, Madasamy. (July, 2022). Energy-Based Approach: Analysis of a Laterally Loaded Pile in Multi-Layered Non-Linear Elastic Soil Strata. Geotechnics. 2. 570-598. 10.3390/geotechnics2030028, which is fully incorporated by reference and made a part hereof, a pile deflection equation is developed.

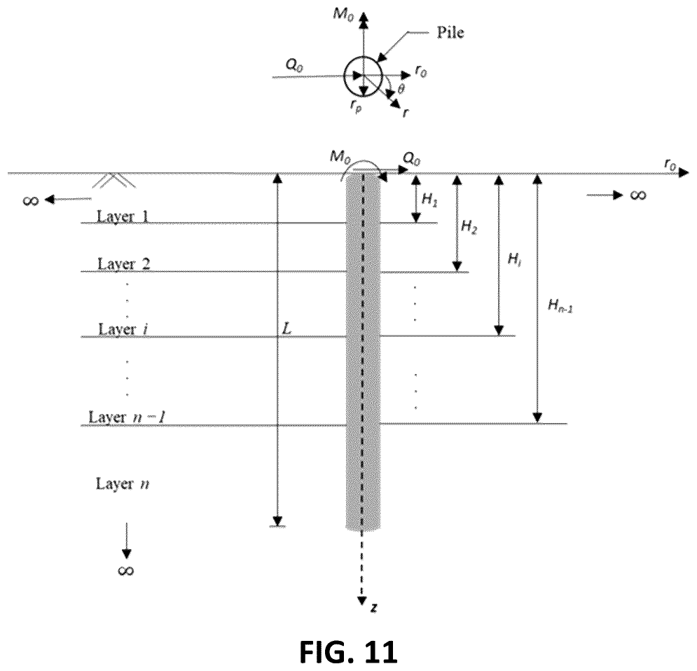

A pile subjected to lateral loading can be modeled as a Euler-Bernoulli beam, especially for long and slender piles in which the pile shear deformation can be neglected for large slenderness ratios of L/D>10. A laterally loaded pile in an isotropic non-linear elastic multi-layered soil medium is shown in FIG. 11. This disclosure considers a pile of length L with circular cross section of radius rₚ. The pile is embedded in n horizontal soil layers, and the pile head is subjected to a horizontal force F₀ accompanied with a bending moment M₀. The horizontal soil layers extend to infinity in the radial direction, and the bottom n^{th} layer extends to infinity in the vertical direction.

The terms H₁, H₂, H₃ . . . Hₙ₋₁ denote the vertical height from the ground surface to the bottom of any layer i. Therefore, the thickness of any layer i is Hᵢ−Hᵢ₋₁ with H₀=0. Due to the axisymmetric problem behavior, a system of cylindrical coordinates (r-θ-z) is chosen, with the origin coinciding with the center of the pile cross section at the pile head, and the z axis coinciding with the pile axis. The pile head is considered to be free, and the tip of the pile is clamped. Another important assumption to be noted is that there is no slippage or separation between the pile and the surrounding soil and between soil layers. The stresses and the displacement within a soil continuum are shown in FIGS. 5A and 5B. At each point in the soil domain, G and λ were calculated (see FIGS. 6A and 6B).

Soil behaves as a linear elastic material at an extremely low range of strain, and the shear modulus starts degrading at a strain as low as 10⁻⁵. Since the soil particles constantly change their position during the application of a load, the resistance offered by the soil mass against deformation also changes; this results in the change in the value of soil modulus with an increase in strain. A non-linear stress-strain curve can be incorporated in an elastic analysis by properly estimating the secant modulus for a given level of strain (or stress). Soil non-linearity is taken into the account by estimating the decay of soil stiffness with strain.

The variation of the shear stress with strain can be described using two parameters, A and n, which were obtained experimentally using a pressuremeter test, as shown in the equation below:

q=A(ε_{q})ⁿ (20)

where q represents the equivalent shear stress, ε_{q} is the deviator shear strain. The decay curves of soil stiffness with strain can be divided into three regions, as shown in FIG. 7. The first region in FIG. 7 represents the very small strain where the stiffness G₀ is constant; the second region comprising small strains starts from ε₀ until ε=0.1%, and the third region exceeds ε=0.1%, indicative of large strains.

In the second region, the stiffness decays rapidly, and in the third region, with large strain levels, the stiffness is the smallest, which concludes that soil stiffness is high at small strain and decreases with large strain. FIG. 8 shows the degradation of soil stiffness with increasing strains for different clay types.

The present disclosure is based on a non-linear elastic model developed by Osman et al. [see above], which assumes the decay of soil stiffness with strain using a power law to describe the stress-strain behavior of soil:

$$G = {{G}_{0} ( \frac{{ε}_{q}}{{ε}_{q 0}} )}^{n} \qquad ( 21 )$$

$$G = a {ε}_{q}^{n} \qquad ( 22 )$$

where

$$a = \frac{{G}_{0}}{{ε}_{q 0}^{n}}$$

is a constant determined empirically; n describes soil non-linearity, which is equal to (−0.5), according to the experimental data analyzed by Osman et al. [86] (see FIG. 9).

$${ε}_{q} = \sqrt{\frac{2}{9} [ {( {ε}_{rr} - {ε}_{θ θ} )}^{2} + {( {ε}_{θ θ} - {ε}_{z z} )}^{2} + {( {ε}_{z z} - {ε}_{rr} )}^{2} ] + \frac{4}{3} ( {ε}_{r θ}^{2} + {ε}_{θ z}^{2} + {ε}_{zr}^{2} )}$$

represents the deviatoric strain; and ε_{q0} is the maximum deviatoric strain with linear elastic behavior, which is equal to 10⁻⁵. Soil stiffness G is estimated by calculating the strain at each location followed by the power law.

For a laterally loaded pile, the displacement at any point within the continuum (FIGS. 5A and 5B) can be expressed as a product of three separable functions, each accounting for one of the dimensions.

uᵣ=u(z)ϕᵣ(r) cos θ (23a)

u_{θ}=−u(z)ϕ_{θ}(r) sin θ (23b)

u_{z}=0 (23c)

where u(z) is a displacement function (with a dimension of length) varying with depth z, representing the deflection of the pile axis; uᵣ, u_{θ}and u_{z} are the soil displacements in the direction r, θ and z; ϕᵣ(r) and ϕ_{θ}(r) are dimensionless soil displacement functions varying with the radial coordinate r, and θ is measured from a vertical reference section (r=r₀) that contains the applied force vector F₀ (FIGS. 5A and 5B). The above functions are set as ϕᵣ(r)=1 and ϕ_{θ}(r)=1 at r=r₀ (i.e., at the pile-soil interface) and ϕᵣ(r)=0 and ϕ_{θ(r)=}0 at ϕ_{θ}=∞. Such an assumption ensures the decrease in the displacement (owing to pile deflection) within the soil mass with increasing radial distance from the pile. Thus, ϕᵣ and ϕ_{θ}vary between 1 at the pile-soil interface to 0 at an infinite radial distance from the pile. It is also reasonable to assume that the vertical displacement of the pile owing to the lateral load and moment is negligible, and this justifies Equation (23c).

In the derivation of the governing differential equations that can capture the non-linear soil response, the soil within each layer is assumed to be elastic and isotropic but heterogeneous (with respect to r and θ but not with respect to z), with no sliding or separation between the soil layers or between the pile and the soil. By solving the equations (valid for elastic, heterogeneous soil) for different magnitudes of load (with appropriate values and variations of soil modulus), the analysis can trace the non-linear progression of pile deflection (due to soil non-linearity) with increasing applied load.

The total potential energy of the pile-soil system, including both the internal and external potential energies, is given by

$$\prod = \frac{1}{2} {E}_{p} {I}_{p} {\int }_{0}^{L} {( \frac{{d}^{2} u}{d {z}^{2}} )}^{2} d z + {\int }_{0}^{∞} {\int }_{0}^{2 π} {\int }_{{r}_{p}}^{∞} \frac{1}{2} {σ}_{ij} {ε}_{ij} r d r d θ dz + {\int }_{L}^{∞} {\int }_{0}^{2 π} {\int }_{0}^{{r}_{p}} \frac{1}{2} {σ}_{ij} {ε}_{ij} r d r d θ d z - {F}_{o} u {\vert}_{z = 0} + {M}_{o} \frac{d u}{d z} {\vert}_{z = 0} \qquad ( 24 )$$

where u is the lateral pile deflection, and σᵢⱼ, εᵢⱼ are the stress and strain tensors in the soil (FIGS. 5A and 5B). The first integral represents the internal potential energy of the pile. The second and third integrals represent the internal potential energy of the continuum. The remaining two terms represent the external potential energy. Soil non-linearity is considered by varying the soil elastic parameters (G and λ) at each discretized nodal point in the soil domain. The stress-strain and strain-displacement relationships at any given nodal point in the soil medium are idealized by the following relationships. The stress-strain relationship is expressed as

$$[ \begin{matrix}{σ}_{rr} \\ {σ}_{θ θ} \\ {σ}_{zz} \\ {τ}_{r θ} \\ {τ}_{rz} \\ {τ}_{θ z}\end{matrix} ] = [ \begin{matrix}λ + 2 G & λ & λ & 0 & 0 & 0 \\ λ & λ + 2 G & λ & 0 & 0 & 0 \\ λ & λ & λ + 2 G & 0 & 0 & 0 \\ 0 & 0 & 0 & G & 0 & 0 \\ 0 & 0 & 0 & 0 & G & 0 \\ 0 & 0 & 0 & 0 & 0 & G\end{matrix} ] [ \begin{matrix}{ε}_{rr} \\ {ε}_{θ θ} \\ {ε}_{zz} \\ {γ}_{r θ} \\ {γ}_{rz} \\ {γ}_{θ z}\end{matrix} ] \qquad ( 25 )$$

where G and λ are the elastic constants of the soil. The strain-displacement relationship is given by

$$[ \begin{matrix}{ε}_{rr} \\ {ε}_{θ θ} \\ {ε}_{zz} \\ {γ}_{r θ} \\ {γ}_{rz} \\ {γ}_{θ z}\end{matrix} ] = [ \begin{matrix}- \frac{\partial {u}_{r}}{\partial r} \\ - \frac{{u}_{r}}{r} - \frac{1}{r} \frac{\partial {u}_{θ}}{\partial θ} \\ - \frac{\partial {u}_{z}}{\partial z} \\ - \frac{1}{r} \frac{\partial {u}_{r}}{\partial θ} - \frac{\partial {u}_{θ}}{\partial r} + \frac{{u}_{θ}}{r} \\ - \frac{\partial {u}_{z}}{\partial r} - \frac{\partial {u}_{r}}{\partial z} \\ - \frac{1}{r} \frac{\partial {u}_{z}}{\partial θ} - \frac{\partial {u}_{θ}}{\partial z}\end{matrix} ] [ \begin{matrix}- u ( z ) \frac{d {ϕ}_{r} ( r )}{dr} cos θ \\ - u ( z ) \frac{{ϕ}_{r} ( r ) - {ϕ}_{θ} ( r )}{r} cos θ \\ 0 \\ u ( z ) \{ \frac{{ϕ}_{r} ( r ) - {ϕ}_{θ} ( r )}{r} + \frac{d {ϕ}_{θ} ( r )}{dr} \} sin θ \\ - \frac{du ( z )}{dz} {ϕ}_{r} ( r ) cos θ \\ \frac{du ( z )}{dz} {ϕ}_{θ} ( r ) sin θ\end{matrix} ] \qquad ( 26 )$$

Combining Equations (25) and (26) gives the strain energy density within any layer:

$$\frac{1}{2} {σ}_{ij} {ε}_{ij} = \frac{1}{2} [ ( λ + 2 G ) {{u}^{2} ( \frac{d {ϕ}_{r}}{dr} )}^{2} {cos}^{2} θ + 2 λ {u}^{2} \frac{d {ϕ}_{r}}{dr} \frac{{ϕ}_{r} - {ϕ}_{θ}}{r} {cos}^{2} θ + ( λ + 2 G ) {u}^{2} \frac{{( {ϕ}_{r} - {ϕ}_{θ} )}^{2}}{{r}^{2}} {cos}^{2} θ + G {u}^{2} \frac{{( {ϕ}_{r} - {ϕ}_{θ} )}^{2}}{{r}^{2}} + {Gu}^{2} {( \frac{d {ϕ}_{θ}}{dr} )}^{2} {sin}^{2} θ + 2 G {u}^{2} \frac{{ϕ}_{r} - {ϕ}_{θ}}{r} \frac{d {ϕ}_{θ}}{dr} {sin}^{2} θ + G {( \frac{du}{dz} )}^{2} {ϕ}_{r}^{2} {cos}^{2} θ + {G ( \frac{du}{dz} )}^{2} {ϕ}_{θ}^{2} {sin}^{2} θ ] \qquad ( 27 )$$

The equilibrium equations are obtained using the principle of minimum potential energy, according to which δΠ=0. Substituting Equation (27) into Equation (24) and applying δΠ=0, we obtain

$$δΠ = {\int }_{0}^{L} {E}_{p} {I}_{p} \frac{{d}^{2} u}{d {z}^{2}} δ ( \frac{{d}^{2} u}{d {z}^{2}} ) dz + {\int }_{0}^{∞} {\int }_{{r}_{p}}^{∞} {\int }_{0}^{2 π} [ ( λ + 2 G ) u δ {u ( \frac{d {ϕ}_{r}}{dr} )}^{2} {cos}^{2} θ + ( λ + 2 G ) {u}^{2} {cos}^{2} θ ( \frac{d {ϕ}_{r}}{dr} ) δ ( \frac{d {ϕ}_{r}}{dr} ) + 2 λ u δ u {cos}^{2} θ \frac{d {ϕ}_{r}}{dr} \frac{( {ϕ}_{r} - {ϕ}_{θ} )}{r} + λ {u}^{2} {cos}^{2} θ \frac{1}{r} ( {ϕ}_{r} - {ϕ}_{θ} ) δ ( \frac{d {ϕ}_{r}}{dr} ) + λ {u}^{2} {cos}^{2} θ \frac{1}{r} \frac{d {ϕ}_{r}}{dr} δ {ϕ}_{r} - λ {u}^{2} {cos}^{2} θ \frac{1}{r} \frac{d {ϕ}_{r}}{dr} δ {ϕ}_{θ} + ( λ + 2 G ) u δ u {cos}^{2} θ \frac{1}{{r}^{2}} {( {ϕ}_{r} - {ϕ}_{θ} )}^{2} + ( λ + 2 G ) {u}^{2} {cos}^{2} θ \frac{1}{{r}^{2}} ( {ϕ}_{r} - {ϕ}_{θ} ) δ {ϕ}_{r} - ( λ + 2 G ) {u}^{2} {cos}^{2} θ \frac{1}{{r}^{2}} ( {ϕ}_{r} - {ϕ}_{θ} ) δ {ϕ}_{θ} + Gu δ u {sin}^{2} θ \frac{1}{{r}^{2}} {( {ϕ}_{r} - {ϕ}_{θ} )}^{2} + 2 Gu δ u {sin}^{2} θ \frac{1}{r} \frac{d {ϕ}_{θ}}{dr} ( {ϕ}_{r} - {ϕ}_{θ} ) + {Gu}^{2} {sin}^{2} θ \frac{1}{{r}^{2}} ( {ϕ}_{r} - {ϕ}_{θ} ) δ {ϕ}_{r} - G {u}^{2} {sin}^{2} θ \frac{1}{{r}^{2}} ( {ϕ}_{r} - {ϕ}_{θ} ) δ {ϕ}_{θ} + {Gu}^{2} {sin}^{2} θ \frac{1}{r} \frac{d {ϕ}_{θ}}{dr} δ {ϕ}_{r} - {Gu}^{2} {sin}^{2} θ \frac{1}{r} \frac{d {ϕ}_{θ}}{dr} δ {ϕ}_{θ} + Gu δ u {sin}^{2} {θ ( \frac{d {ϕ}_{θ}}{dr} )}^{2} + {Gu}^{2} {sin}^{2} θ \frac{d {ϕ}_{θ}}{dr} δ ( \frac{d {ϕ}_{θ}}{dr} ) + G {u}^{2} {sin}^{2} θ \frac{1}{r} ( {ϕ}_{r} - {ϕ}_{θ} ) δ ( \frac{d {ϕ}_{θ}}{dr} ) + G \frac{d u}{d z} δ ( \frac{d u}{d z} ) {ϕ}_{r}^{2} {cos}^{2} θ + {G ( \frac{d u}{d z} )}^{2} {cos}^{2} {θϕ}_{r} δ {ϕ}_{r} + G \frac{d u}{d z} δ ( \frac{d u}{d z} ) {ϕ}_{θ}^{2} {sin}^{2} θ + {G ( \frac{d u}{d z} )}^{2} {sin}^{2} {θϕ}_{θ} δ {ϕ}_{θ} ] r d θ d rdz + π {r}_{p}^{2} {\int }_{L}^{∞} G \frac{d u}{d z} δ ( \frac{d u}{d z} ) dz - {F}_{o} δ u {\vert}_{z = 0} + {M}_{o} δ ( \frac{d u}{d z} ) {\vert}_{z = 0} = 0 \qquad ( 28 )$$

The variations δu,δϕᵣ, and δϕ_{θ} are functions of u(z),ϕᵣ (r) and ϕ_{θ} (r) and are independent. To obtain the pile governing equation, from Equation (28), all terms associated with δu, δ(du/dz) will be collected. Furthermore, the terms that are related to δϕᵣ and δϕ_{θ} will be collected to obtain the governing equation of the soil.

The governing equation of piles can be obtained by collecting the terms associated with δu and δ(du/dz) for (0≤z≤L) from Equation (28) and then equating the summation to zero.

$${\int }_{0}^{L} {E}_{p} {I}_{p} \frac{{d}^{2} u}{d {z}^{2}} δ ( \frac{{d}^{2} u}{d {z}^{2}} ) d z + π {r}_{p}^{2} {\int }_{L}^{∞} G \frac{d u}{d z} δ ( \frac{d u}{d z} ) d z + {\int }_{0}^{∞} {\int }_{{r}_{p}}^{∞} {\int }_{0}^{2 π} [ ( λ + 2 G ) u δ {u ( \frac{d {ϕ}_{r}}{dr} )}^{2} {cos}^{2} θ + 2 λ u δ u {cos}^{2} θ \frac{d {ϕ}_{r}}{dr} \frac{( {ϕ}_{r} - {ϕ}_{θ} )}{r} + Gu δ u {sin}^{2} {θ ( \frac{d {ϕ}_{θ}}{dr} )}^{2} + G \frac{d u}{d z} δ ( \frac{d u}{d z} ) {ϕ}_{r}^{2} {cos}^{2} θ + G \frac{d u}{d z} δ ( \frac{d u}{d z} ) {ϕ}_{θ}^{2} {sin}^{2} θ + Gu δ u {sin}^{2} θ \frac{1}{{r}^{2}} {( {ϕ}_{r} - {ϕ}_{θ} )}^{2} + ( λ + 2 G ) u δ u {cos}^{2} θ \frac{1}{{r}^{2}} {( {ϕ}_{r} - {ϕ}_{θ} )}^{2} ] r d θ d rdz - {F}_{o} δ u {\vert}_{z = 0} + {M}_{o} δ ( \frac{d u}{d z} ) {\vert}_{z = 0} = 0 \qquad ( 29 )$$

The governing equation becomes

$${E}_{p} {I}_{p} \frac{{d}^{4} u}{d {z}^{4}} - C \frac{{d}^{2} u}{d {z}^{2}} + k u = 0$$

$$where$$

$$C = {\int }_{{r}_{p}}^{∞} {\int }_{0}^{2 π} {G}_{s i} ( {ϕ}_{r}^{2} {cos}^{2} θ + {ϕ}_{θ}^{2} {sin}^{2} θ ) rd θ$$

where i denotes the layer number from the surface to the length of the pile

Cₛ=∫ᵣ_{ₚ}^{∞}∫₀^{2π}Gₛⱼ(ϕᵣ² cos² θ+ϕ_{θ}² sin² θ)rdθ

and where j represents the layer number from pile length to infinity.

$$k = {\int }_{{r}_{p}}^{∞} {\int }_{0}^{2 π} ( ( λ + G ) {( \frac{d {ϕ}_{r}}{d r} )}^{2} {cos}^{2} θ + 2 λ \frac{1}{r} \frac{d {ϕ}_{r}}{d r} ( {ϕ}_{r} - {ϕ}_{θ} ) {cos}^{2} θ + ( λ + G ) \frac{{( {ϕ}_{r} - {ϕ}_{θ} )}^{2}}{{r}^{2}} {cos}^{2} θ + G \frac{{( {ϕ}_{r} - {ϕ}_{θ} )}^{2}}{{r}^{2}} {sin}^{2} θ + 2 G \frac{( {ϕ}_{r} - {ϕ}_{θ} )}{r} \frac{d {ϕ}_{θ}}{d r} {sin}^{2} θ + {G ( \frac{d {ϕ}_{θ}}{d r} )}^{2} {sin}^{2} θ ) rd θ dr$$

The fourth-order differential Equation (30) can be solved using a central finite difference scheme represented as:

$${E}_{p} {I}_{p} ( \frac{{u}_{i - 2} - 4 {u}_{i - 1} + 6 {u}_{i} - 4 {u}_{i + 1} + {u}_{i + 2}}{Δ {z}^{4}} ) - C ( \frac{- {u}_{i - 1} + {u}_{i + 1}}{Δ z} ) + k {u}_{i} = 0$$

where i denotes the ith node in z direction, and Δz is the distance between two nodes. At each point in the soil domain, λ and G were calculated (see FIGS. 6A and 6B).

Similar to the pile governing equation, the soil governing equation can be formulated by considering the variations of ϕᵣ(r) and ϕ_{θ}(r). Collecting the terms associated with ϕᵣ and ϕ_{θ} over the domain r₀≤r≤∞ and equating the summation to zero yields

$${\int }_{0}^{∞} {\int }_{{r}_{p}}^{∞} {\int }_{0}^{2 π} [ ( λ + 2 G ) {u}^{2} {cos}^{2} θ ( \frac{d {ϕ}_{r}}{dr} ) δ ( \frac{d {ϕ}_{r}}{dr} ) + {Gu}^{2} {sin}^{2} θ \frac{1}{r} ( \frac{d {ϕ}_{θ}}{dr} ) δ {ϕ}_{r} + λ {u}^{2} {cos}^{2} θ \frac{( {ϕ}_{r} - {ϕ}_{θ} )}{r} δ ( \frac{d {ϕ}_{r}}{dr} ) + λ {u}^{2} {cos}^{2} θ \frac{1}{r} ( \frac{d {ϕ}_{r}}{dr} ) δ {ϕ}_{r} + {Gu}^{2} {sin}^{2} θ \frac{1}{{r}^{2}} ( {ϕ}_{r} - {ϕ}_{θ} ) δ {ϕ}_{r} + ( λ + 2 G ) {u}^{2} {cos}^{2} θ \frac{1}{{r}^{2}} ( {ϕ}_{r} - {ϕ}_{θ} ) δ {ϕ}_{r} + G {cos}^{2} {θ ( \frac{d u}{d z} )}^{2} {ϕ}_{r} δ {ϕ}_{r} ] r d r d θ d z = 0 \qquad ( 31 )$$

$${\int }_{0}^{∞} {\int }_{{r}_{p}}^{∞} {\int }_{0}^{2 π} [ - G {u}^{2} {sin}^{2} θ ( \frac{d {ϕ}_{θ}}{dr} ) δ {ϕ}_{θ} - λ {u}^{2} {cos}^{2} θ \frac{1}{r} ( \frac{d {ϕ}_{r}}{dr} ) δ {ϕ}_{θ} - G {u}^{2} {sin}^{2} θ \frac{1}{{r}^{2}} ( {ϕ}_{r} - {ϕ}_{θ} ) δ {ϕ}_{θ} - ( λ + 2 G ) {u}^{2} {cos}^{2} θ \frac{1}{{r}^{2}} ( {ϕ}_{r} - {ϕ}_{θ} ) δ {ϕ}_{θ} + G {u}^{2} {sin}^{2} θ ( \frac{d {ϕ}_{θ}}{dr} ) δ ( \frac{d {ϕ}_{θ}}{dr} ) + {Gu}^{2} {sin}^{2} θ \frac{( {ϕ}_{r} - {ϕ}_{θ} )}{r} δ ( \frac{d {ϕ}_{θ}}{dr} ) + G {sin}^{2} {θ ( \frac{du}{dz} )}^{2} {ϕ}_{θ} δ {ϕ}_{θ} ] r d r d θ d z = 0 \qquad ( 32 )$$

Simplifying Equations (31) and (32) gives

$${\int }_{{r}_{p}}^{∞} ( {m}_{s 1} ( \frac{d {ϕ}_{r}}{dr} ) δ ( \frac{d {ϕ}_{r}}{dr} ) + {m}_{s 3} \frac{1}{r} ( \frac{d {ϕ}_{r}}{dr} ) δ {ϕ}_{r} + {m}_{s 3} \frac{( {ϕ}_{r} - {ϕ}_{θ} )}{r} δ ( \frac{d {ϕ}_{r}}{dr} ) + {m}_{s 1} \frac{1}{{r}^{2}} ( {ϕ}_{r} - {ϕ}_{θ} ) δ {ϕ}_{r} + {m}_{s 2} \frac{1}{{r}^{2}} ( {ϕ}_{r} - {ϕ}_{θ} ) δ {ϕ}_{r} + {m}_{s 2} \frac{1}{r} ( \frac{d {ϕ}_{θ}}{dr} ) δ {ϕ}_{r} + {n}_{s 1} {ϕ}_{r} δ {ϕ}_{r} ) d r = 0 \qquad ( 33 )$$

$${\int }_{p}^{∞} ( - {m}_{s 2} ( \frac{d {ϕ}_{θ}}{dr} ) δ ( \frac{d {ϕ}_{θ}}{dr} ) - {m}_{s 3} \frac{1}{r} ( \frac{d {ϕ}_{r}}{dr} ) δ {ϕ}_{θ} - {m}_{s 2} \frac{1}{{r}^{2}} ( {ϕ}_{r} - {ϕ}_{θ} ) δ {ϕ}_{θ} - {m}_{s 1} \frac{1}{{r}^{2}} ( {ϕ}_{r} - {ϕ}_{θ} ) δ {ϕ}_{θ} + {m}_{s 2} ( \frac{d {ϕ}_{θ}}{dr} ) δ ( \frac{d {ϕ}_{θ}}{dr} ) + {m}_{s 2} \frac{( {ϕ}_{r} - {ϕ}_{θ} )}{r} δ ( \frac{d {ϕ}_{θ}}{dr} ) {n}_{s 2} {ϕ}_{θ} δ {ϕ}_{θ} ) d r = 0 \qquad ( 34 )$$

where nₛ₁, nₛ₂, mₛ₁, mₛ₂ and mₛ₃ for homogeneous and non-homogeneous soil comprising multi-layer soil summations with i representing the number of layers and n being the last layer number are given below

$${m}_{s 1} ( r ) = {\int }_{0}^{∞} {\int }_{0}^{2 π} ( {λ}_{s} + 2 {G}_{s} ) {u}^{2} {cos}^{2} θ rd θ dz = {\sum }_{i = n}^{n} {\int }_{{H}_{i - 1}}^{{H}_{i}} {\int }_{0}^{2 π} ( {λ}_{s i} + 2 {G}_{s i} ) {u}_{i}^{2} {cos}^{2} θ rd θ dz \qquad ( 35 a )$$

$${m}_{s 2} ( r ) = {\int }_{0}^{∞} {\int }_{0}^{2 π} {G}_{s} {u}^{2} {sin}^{2} θ r d θ d z = {\sum }_{i = n}^{n} {\int }_{{H}_{i - 1}}^{{H}_{i}} {\int }_{0}^{2 π} {G}_{s i} {u}_{i}^{2} {sin}^{2} θ rd θ dz \qquad ( 35 b )$$

$${m}_{s 3} ( r ) = {\int }_{0}^{∞} {\int }_{0}^{2 π} {λ}_{s} {u}^{2} {cos}^{2} θ rd θ dz = {\sum }_{i = n}^{n} {\int }_{{H}_{i - 1}}^{{H}_{i}} {\int }_{0}^{2 π} {λ}_{s i} {u}_{i}^{2} {cos}^{2} θ rd θ dz \qquad ( 35 c )$$

$${n}_{s 1} ( r ) = {\int }_{0}^{∞} {\int }_{0}^{2 π} {G}_{s} ( \frac{du}{dz} ) {cos}^{2} θ r d θ d z = {\sum }_{i = n}^{n} {\int }_{{H}_{i - 1}}^{{H}_{i}} {\int }_{0}^{2 π} {{G}_{s i} ( \frac{d {u}_{i}}{d z} )}^{2} {cos}^{2} θ rd θ dz \qquad ( 35 d )$$

$${n}_{s 1} ( r ) = {\int }_{0}^{∞} {\int }_{0}^{2 π} {G}_{s} ( \frac{du}{dz} ) {sin}^{2} θ rd θ dz = {\sum }_{i = n}^{n} {\int }_{{H}_{i - 1}}^{{H}_{i}} {\int }_{0}^{2 π} {{G}_{s i} ( \frac{d {u}_{i}}{d z} )}^{2} {sin}^{2} θ rd θ dz \qquad ( 35 e )$$

Equations (33) and (34) can be simplified further using integration by parts of the terms that consist of δ((dϕᵣ)/dr) and δ((dϕ_{θ})/dr), respectively. The governing equation is then obtained by dividing the resulting equations of (33) by (−mₛ₁) and (34) by (−mₘ₂).

$$\frac{{d}^{2} {ϕ}_{r}}{{dr}^{2}} + \frac{1}{{m}_{S 1}} \frac{d {m}_{S 1}}{dr} \frac{d {ϕ}_{r}}{dr} - \{ \frac{1}{{r}^{2}} \frac{{m}_{S 1} + {m}_{S 2} + {m}_{S 3}}{{m}_{S 1}} - \frac{1}{r} \frac{1}{{m}_{S 1}} \frac{d {m}_{S 3}}{dr} + \frac{{n}_{S 1}}{{m}_{S 1}} \} {ϕ}_{r} = \frac{{m}_{S 2} + {m}_{S 3}}{{m}_{S 1}} \frac{1}{r} \frac{d {ϕ}_{θ}}{dr} - \{ \frac{1}{{r}^{2}} \frac{{m}_{S 1} + {m}_{S 2} + {m}_{S 3}}{{m}_{S 1}} - \frac{1}{r} \frac{1}{{m}_{S 1}} \frac{d {m}_{S 3}}{dr} \} {ϕ}_{θ} \qquad ( 36 )$$

$$\frac{{d}^{2} {ϕ}_{θ}}{{dr}^{2}} + \frac{1}{{m}_{S 2}} \frac{d {m}_{S 2}}{dr} \frac{d {ϕ}_{θ}}{dr} - \{ \frac{1}{{r}^{2}} \frac{{m}_{S 1}}{{m}_{S 2}} + \frac{1}{r} \frac{1}{{m}_{S 2}} \frac{d {m}_{S 2}}{dr} + \frac{{n}_{S 2}}{{m}_{S 2}} \} {ϕ}_{θ} = \frac{{m}_{S 2} + {m}_{S 3}}{{m}_{S 2}} \frac{1}{r} \frac{d {ϕ}_{r}}{dr} - \{ \frac{1}{{r}^{2}} \frac{{m}_{S 1}}{{m}_{S 2}} + \frac{1}{r} \frac{1}{{m}_{S 2}} \frac{d {m}_{S 2}}{dr} \} {ϕ}_{r} \qquad ( 37 )$$

Considering the soil boundary conditions ϕᵣ=1 at r=r₀; ϕᵣ=0 at r→∞; ϕ_{θ}=1 at r=r₀; and ϕ_{θ}=0 at r→∞, the governing differential equations of soil can be rewritten as

$$\frac{{d}^{2} {ϕ}_{r}}{{dr}^{2}} + {y}_{1} \frac{d {ϕ}_{r}}{dr} - {y}_{2} {ϕ}_{r} = {y}_{3} \frac{d {ϕ}_{θ}}{dr} - {y}_{4} {ϕ}_{θ} \qquad ( 38 )$$

$$\frac{{d}^{2} {ϕ}_{θ}}{{dr}^{2}} + {y}_{5} \frac{d {ϕ}_{θ}}{dr} - {y}_{6} {ϕ}_{θ} = - {y}_{7} \frac{d {ϕ}_{r}}{dr} - {y}_{8} {ϕ}_{r} \qquad ( 39 )$$

$$where$$

$${y}_{1} = \frac{1}{{m}_{S 1}} \frac{d {m}_{S 1}}{dr} \qquad ( 40 a )$$

$${y}_{1} = \frac{1}{{m}_{S 1}} \frac{d {m}_{S 1}}{dr} \qquad ( 40 b )$$

$${y}_{3} = \frac{1}{r} \frac{{m}_{S 2} + {m}_{S 3}}{{m}_{S 1}} \qquad ( 40 c )$$

$${y}_{4} = \frac{1}{{r}^{2}} \frac{{m}_{S 1} + {m}_{S 2} + {m}_{S 3}}{{m}_{S 1}} - \frac{1}{r} \frac{1}{{m}_{S 1}} \frac{d {m}_{S 3}}{dr} \qquad ( 40 d )$$

$${y}_{5} = \frac{1}{{m}_{S 2}} \frac{d {m}_{S 2}}{dr} \qquad ( 40 e )$$

$${y}_{6} = \frac{1}{{r}^{2}} \frac{{m}_{S 1}}{{m}_{S 2}} + \frac{1}{r} \frac{1}{{m}_{S 2}} \frac{d {m}_{S 2}}{dr} + \frac{{n}_{S 2}}{{m}_{S 2}} \qquad ( 40 f )$$

$${y}_{7} = \frac{1}{r} \frac{{m}_{S 2} + {m}_{S 3}}{{m}_{S 2}} \qquad ( 40 g )$$

$${y}_{8} = \frac{1}{{r}^{2}} \frac{{m}_{S 1}}{{m}_{S 2}} + \frac{1}{r} \frac{1}{{m}_{S 2}} \frac{d {m}_{S 2}}{dr} \qquad ( 40 h )$$

The disclosed embodiments operate on an iterative basis. The pile deflection equation (Equation (30)) can be solved when the soil and geometry related parameters k, C and m are known; however, these parameters are dependent on the unknown dimensionless soil functions, ϕᵣ and ϕ_{θ}, which can be estimated by calculating y₁, y₂, y₃, y₄, y₅, y₆, y₇ and y₈. Soil deformation is calculated in radial and circumference directions, then calculated in the depth direction. To obtain the soil displacement, the initial numbers of these values, y₁, y₂, y₃, y₄, y₅, y₆, y₇ and y₈, must be assumed. Then, they are inserted into Equations (38) and (39), from which the soil parameters k and C are obtained as a result of the pile displacement. New values of y₁, y₂, y₃, y₄, y₅, y₆, y₇ and y₈ can then be inserted into Equations (38) and (39) to evaluate ϕᵣ and ϕ_{θ}which are then inserted into Equation (30) to obtain the pile displacement u, so an iteration technique is needed to satisfy the condition

$$\frac{{γ}_{o l d} - {γ}_{n e w}}{{γ}_{o l d}} < 0.001 .$$

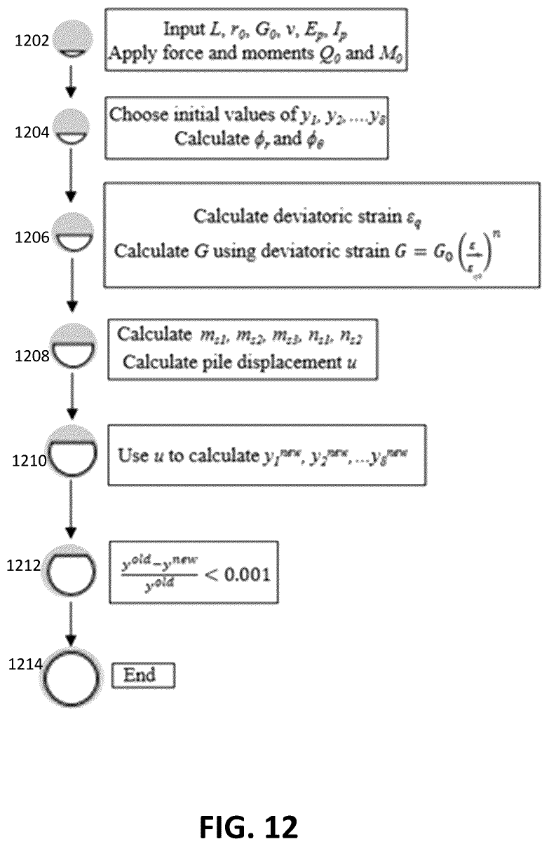

FIG. 12 shows the flow chart of the iterative solution procedure for a laterally-loaded pile. The disclosed method comprises 1202, inputting values r₀, L, λ, G₀, Eₚ, Iₚ, and applying force and moments, Q₀ and M₀. At 1204, choosing initial values of y₁, y₂, y₃, y₄, y₅, y₆, y₇ and y₈, and calculating ϕᵣ and ϕ_{θ}. At 1206, calculating deviatoric strain ε_{q}, ad using the deviatoric strain to calculate soil stiffness, G, where

$$G = {{G}_{0} ( \frac{{ε}_{q}}{{ε}_{qo}} )}^{n} .$$

At 1208, calculate nₛ₁, nₛ₂, mₛ₁, mₛ₂ and mₛ₃, and then calculate the pile displacement u. At 1210, use the pile displacement u to calculate y₁^{new} y₂^{new} y₃^{new} y₄^{new} y₅^{new} y₆^{new} y₇^{new} and y₈^{new}. At 1212, it is determined whether a condition ((y_{old}−y_{new})/y_{old}<0.001)is true. At 1214, steps 1202-1212 are repeated until the condition ((y_{old}−y_{new})/y_{old}<0.001) is true.

In examples, a computer system may be included and/or operated within which a set of instructions for implementing the disclosed embodiments of the methods are execute to form a machine and for causing the machine (e.g., computer, cytometer, smartphone) to perform any one or more of the methodologies discussed herein, may be executed. In alternative embodiments, the machine may be connected (e.g., networked) to other machines in a local area network (LAN), an intranet, an extranet, or the Internet. The machine may operate in the capacity of a server or a client machine in a client-server network environment, or as a peer machine in a peer-to-peer (or distributed) network environment. It is understood that the machine may be a personal computer (PC), a tablet PC, a set-top box (STB), a personal digital assistant (PDA), a cellular telephone, a web appliance, a server, a network router, switch or bridge, or any machine capable of executing the computer application or another other set of instructions (sequential or otherwise) that specify actions to be taken by that machine. Further, the term “machine” shall also be taken to include any collection of machines that individually or jointly execute a set (or multiple sets) of instructions to perform any one or more of the methodologies discussed herein.

The exemplary machine may include a processing device, a main memory (e.g., read-only memory (ROM), flash memory, dynamic random access memory (DRAM) (such as synchronous DRAM (SDRAM) or Rambus DRAM (RDRAM), etc.), a static memory (e.g., flash memory, static random access memory (SRAM), etc.), and a data storage device, which communicate with each other via a bus.

Processing device represents one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or a processor implementing other instruction sets, or processors implementing a combination of instruction sets. Processing device may also be one or more special-purpose processing devices such as an application specific integrated circuit (ASIC), a field programmable gate array (FPGA), a digital signal processor (DSP), network processor, or the like. Processing device is configured to execute listings manager logic for performing the operations and steps discussed herein.

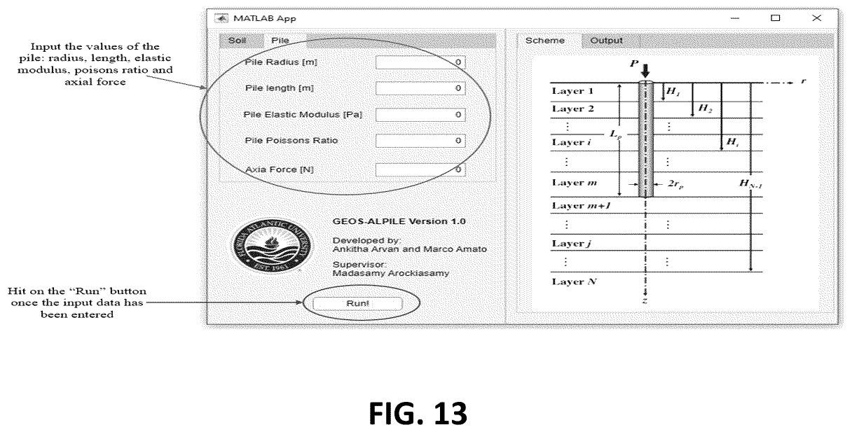

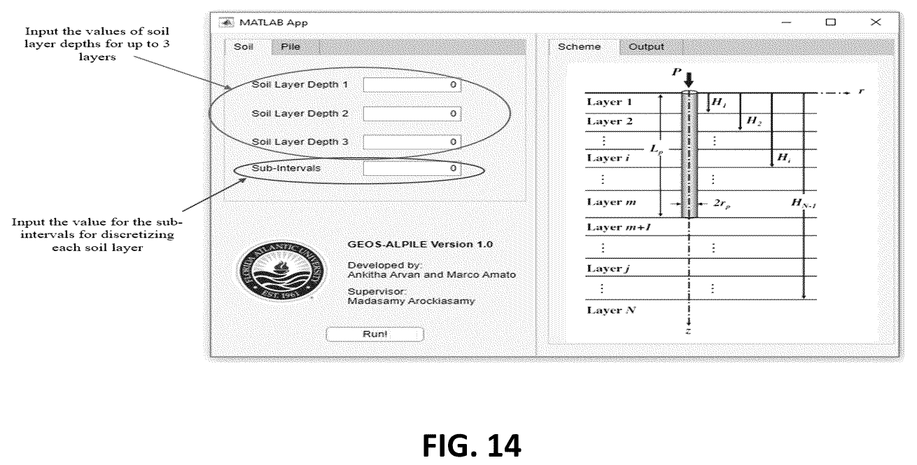

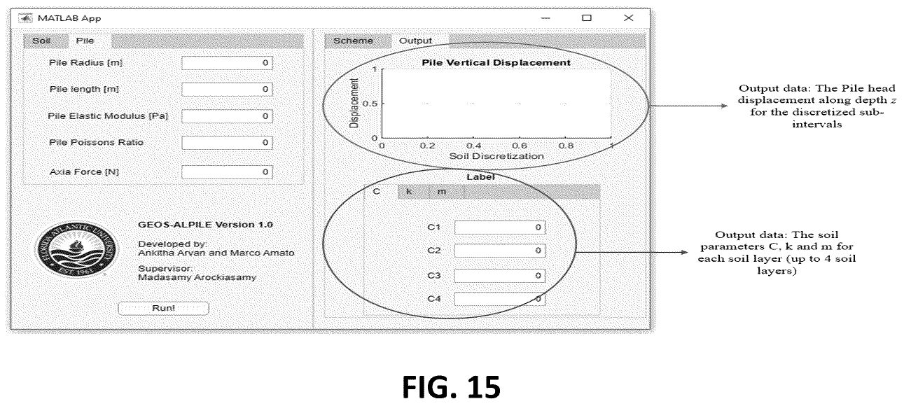

Computer system may further include a network interface device (e.g., GUI). Computer system also may include a video display unit (e.g., a liquid crystal display (LCD) or a cathode ray tube (CRT)), an alphanumeric input device (e.g., keyboard, keypad), a cursor control device (e.g., mouse. touchpad), and a signal generation device (e.g., a speaker). For example, FIGS. 13, 14 and 15 are exemplary annotated screenshots of graphical user interfaces of embodiments of software according to the invention.

Data storage device may include a machine-readable storage medium (or more specifically a computer-readable storage medium) having one or more sets of instructions (e.g., reference generation module) embodying any one or more of the methodologies of functions described herein. The reference generation module may also reside, completely or at least partially, within main memory and/or within processing device during execution thereof by computer system; main memory and processing device also constituting machine-readable storage media. The reference generation module may further be transmitted or received over a network via network interface device.

Machine-readable storage medium may also be used to store the device queue manager logic persistently. While a non-transitory machine-readable storage medium is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instruction for execution by the machine and that causes the machine to perform any one or more of the methodologies of the present invention. The term “machine-readable storage medium” shall accordingly be taken to include, but not be limited to, solid-state memories, and optical and magnetic media.

The components and other features described herein can be implemented as discrete hardware components or integrated in the functionality of hardware components such as ASICs, FPGAs, DSPs or similar devices. In addition, these components can be implemented as firmware or functional circuitry within hardware devices. Further, these components can be implemented in any combination of hardware devices and software components.

Some portions of the detailed descriptions are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

The instructions may include, for example, computer-executable instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, objects, components, and data structures, and the like that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described therein.

In the aforementioned description, numerous details are set forth. It will be apparent, however, to one skilled in the art, that the disclosure may be practiced without these specific details. In some instances, well-known structures and devices are shown in block diagram form, rather than in detail, in order to avoid obscuring the disclosure.

The disclosure is related to an apparatus for performing the operations herein. This apparatus may be specially constructed for the required purposes or it may comprise a general purpose computing device selectively activated or reconfigured by a computer program stored therein. Such a computer program may be stored in a non-transitory computer readable storage medium, such as, but not limited to, any type of disk including floppy disks, optical disks, CD-ROMs and magnetic-optical disks, read-only memories (ROMs), random access memories (RAMs), EPROMs, EEPROMs, magnetic or optical cards, flash memory devices including universal serial bus (USB) storage devices (e.g., USB key devices) or any type of media suitable for storing electronic instructions, each of which may be coupled to a computer system bus.

While the invention has been described in detail and with reference to specific examples thereof, it will be apparent to one skilled in the art that various changes and modifications can be made therein without departing from the spirit and scope thereof.

What is claimed is:

1. A method for analyzing displacement responses of a pile subjected to at least one loading condition selected from the group consisting of an axial load, a lateral load, and a bending moment, said method comprising:
(a) inputting values r₀, L, λ, G₀, Eₚ, Pₜ, and ν;
(b) calculating γ_{1,old} and y_{2,old};
(c) determining integrations of soil parameters C, k and m;
(d) calculating soil dimensionless function ϕ;
(e) calculating pile displacement ν;
(f) calculating γ_{1,new} and γ_{2,new};
(g) determining whether a condition (γ_{old}−γ_{new})/γ_{old}<0.001 is true; and
(h) repeating steps (a)-(g) until the condition is true.

2. The method of claim 1, wherein the pile is installed in nonlinear soil.

3. The method of claim 2, wherein the soil is assumed to be nonlinear elastic and perfectly plastic.

4. The method of claim 2, wherein soil moduli (λ and G₀) are assumed to vary in radial, circumference and depth directions according to strain and stress levels.

5. The method of claim 1, wherein the pile comprises a plurality of piles.

6. The method of claim 1, wherein the method is coded into executable instructions, sored in a memory, and executed by a processor.

7. The method of claim 5, wherein the executable instructions are executed using a finite difference method (FDM).

8. The method of claim 1, wherein soil moduli (λ and G₀) are assumed to vary in radial, circumference and depth directions according to strain and stress levels.

9. The method of claim 1, wherein the loading condition is the axial (vertical) load and a head of the pile (pile head) is assumed to be free, and a tip of the pile is assumed to be clamped.

10. The method of claim 8, wherein calculating pile displacement ν comprises determining pile head deflection caused by the action of the vertical load at the pile head.

11. A non-transitory machine-readable storage medium comprising instructions executable by a processing resource of a computing device to cause the processing resource to perform a method of analyzing displacement responses of a pile subjected to an axial loading condition, said method comprising:
(a) inputting values r₀, L, λ, G₀, Eₚ, Pₜ, and ν;
(b) calculating γ_{1,old} and γ_{2,old};
(c) determining integrations of soil parameters C, k and m;
(d) calculating soil dimensionless function ϕ;
(e) calculating pile displacement ν;
(f) calculating γ_{1,new} and γ_{2,new};
(g) determining whether a condition (γ_{old}−γ_{new})/γ_{old}<0.001 is true; and
(h) repeating steps (a)-(g) until the condition is true.

12. The non-transitory machine-readable storage medium of claim 11, wherein the pile is installed in nonlinear soil.

13. The non-transitory machine-readable storage medium of claim 12, wherein the soil is assumed to be nonlinear elastic and perfectly plastic.

14. The non-transitory machine-readable storage medium of claim 12, wherein soil moduli (λ and G₀) are assumed to vary in radial, circumference and depth directions according to strain and stress levels.

15. The non-transitory machine-readable storage medium of claim 11, wherein the pile comprises a plurality of piles.

16. The non-transitory machine-readable storage medium of claim 15, wherein the instructions executable by a processing resource are executed using a finite difference method (FDM).

17. The non-transitory machine-readable storage medium of claim 11, wherein soil moduli (λ and G₀) are assumed to vary in radial, circumference and depth directions according to strain and stress levels.

18. The non-transitory machine-readable storage medium of claim 11, wherein the loading condition is the axial (vertical) load and a head of the pile (pile head) is assumed to be free, and a tip of the pile is assumed to be clamped.

19. The non-transitory machine-readable storage medium of claim 18, wherein calculating pile displacement v comprises determining pile head deflection caused by the action of the vertical load at the pile head.

20. A method for analyzing displacement responses of a pile subjected to a lateral loading condition, said method comprising the following steps:
(a) inputting values r₀, L, λ, G₀, Eₚ, and Iₚ, and applying force and moments, Q₀ and M₀;
(b) choosing initial values of y₁, y₂, y₃, y₄, y₅, y₆, y₇ and y₈, and calculating ϕᵣ and ϕ_{θ};
(c) calculating deviatoric strain ε_{q}, and using the deviatoric strain to calculate soil stiffness, G, where
$$G = {{G}_{0} ( \frac{{ε}_{q}}{{ε}_{qo}} )}^{n} ;$$
(d) calculate nₛ₁, nₛ₂, mₛ₁, mₛ₂ and mₛ₃;
(e) calculating pile displacement u;
(f) calculating calculate y₁^{new} y₂^{new} y₃^{new} y₄^{new} y₅^{new} y₆^{new} y₇^{new} and y₈^{new};
(g) determining whether a condition y_{old}−y_{new})/y_{old}<0.001 is true; and
(h) repeating steps (a)-(g) until the condition is true.

21. A non-transitory machine-readable storage medium comprising instructions executable by a processing resource of a computing device to cause the processing resource to perform a method of analyzing displacement responses of a pile subjected to a lateral loading condition, said method comprising:
(a) inputting values r₀, L, λ, G₀, Eₚ, and Iₚ, and applying force and moments, Q₀ and M₀;
(b) choosing initial values of y₁, y₂, y₃, y₄, y₅, y₆, y₇ and y₈, and calculating ϕᵣ and ϕ_{θ};
(c) calculating deviatoric strain ε_{q}, and using the deviatoric strain to calculate soil stiffness, G, where
$$G = {{G}_{0} ( \frac{{ε}_{q}}{{ε}_{qo}} )}^{n} ;$$
(d) calculate nₛ₁, nₛ₂, mₛ₁, mₛ₂ and mₛ₃;
(e) calculating pile displacement u;
(f) calculating calculate y₁^{new} y₂^{new} y₃^{new} y₄^{new} y₅^{new} y₆^{new} y₇^{new} and y₈^{new};
(g) determining whether a condition y_{old}−y_{new})/y_{old}<0.001 is true; and
(h) repeating steps (a)-(g) until the condition is true.
